(19) United States
(12) Patent Application Publication
(10) Pub. No.: US 2012/0267662 A1
(43) Pub. Date: Oct. 25, 2012

(54) LIGHT-EMITTING DIODE CHIP

(75) Inventors: Markus Maute, Alteglofsheim (DE); Tony Albrecht, Bad Abbach (DE); Anna Kasprzak-Zablocka, Regensburg (DE)

(73) Assignee: OSRAM OPTO SEMICONDUCTORS GMBH, Regensburg (DE)

(21) Appl. No.: 13/388,265

(22) PCT Filed: Jul. 13, 2010
(86) PCT No.: PCT/EP2010/060077

§ 371 Date: Jul. 16, 2012

(30) Foreign Application Priority Data
Jul. 31, 2009 (DE) 10 2009 035 429.8

(51) Int. Cl. H01L 33/60

(52) U.S. Cl. 257/98; 438/29; 438/33; 257/E33.06

(57) ABSTRACT

A light-emitting diode chip comprises a semiconductor body (1) having a first (1A) and a second region (1B); an active zone (2) within the semiconductor body (1), which active zone, during the operation of the light-emitting diode chip (100), emits electromagnetic radiation through a radiation coupling-out area (11) formed at least in places by a first main area (111) of the semiconductor body (1); at least one trench (3) in the semiconductor body (1) wherein parts of the semiconductor body (1) are removed in the region of the trench, wherein the at least one trench (3) extends at least as far as the active zone (2), the at least one trench (3) completely surrounds the first region (1A) in a lateral direction, and the second region (1B) completely surrounds the at least one trench (3) and the first region (1A) in a lateral direction.

A light-emitting diode chip and a method for producing a light-emitting diode chip are specified.

This Patent Application claims the priority of German Patent Application 10 2009 035 429.8, the disclosure content of which is hereby incorporated by reference.

One object to be achieved consists in specifying a light-emitting diode chip which is protected against external mechanical damage and has an increased lifetime.

In accordance with at least one embodiment, the light-emitting diode chip comprises a semiconductor body having a first and a second region. By way of example, the semiconductor body is formed with an epitaxially grown semiconductor layer sequence. By way of example, the semiconductor body is formed completely by the first and the second regions, in which case the first and the second regions are then likewise formed with the epitaxially grown semiconductor layer sequence. In this context, “region” means a three-dimensional partial structure of the semiconductor body which forms and shapes the semiconductor body in places.

In accordance with at least one embodiment, the light-emitting diode chip comprises an active zone within the semiconductor body. The active zone can be a layer which, during the operation of the light-emitting diode chip emits electromagnetic radiation in a wavelength range within the ultraviolet to infrared spectral range of the electromagnetic radiation.

In accordance with at least one embodiment, the active zone, during the operation of the light-emitting diode chip, emits electromagnetic radiation through a radiation coupling-out area formed at least in places by a first main area of the semiconductor body. In this case, the first main area of the semiconductor body is a part of the outer area of the semiconductor body. The first main area runs for example perpendicularly to the growth direction of the epitaxially produced semiconductor body. The electromagnetic radiation generated in the active zone within the semiconductor body is coupled out from the semiconductor body at least in part through the radiation coupling-out area.

In accordance with at least one embodiment, the light-emitting diode chip comprises at least one trench in the semiconductor body, wherein parts of the semiconductor body are removed in the region of the trench. That is to say that at least in places the trench is bounded laterally by the semiconductor body. In this context, it is conceivable for the at least one trench to have a base area lying opposite an opening of the trench and also two side areas connected to one another by the base area. Both the side areas and the base area can then be formed by the semiconductor body. The trench is produced by material removal, for example. The trench is therefore a cutout in the semiconductor body.

In accordance with at least one embodiment, the at least one trench extends at least as far as the active zone. That is to say that the at least one trench runs at least between the active zone and the main area of the semiconductor body and at these locations penetrates through the intervening material layers. It is likewise conceivable for the at least one trench to penetrate through the active zone. At locations at which the at least one trench runs, the active zone is then “subdivided”. If the semiconductor body has a plurality of active zones stacked one above another, then the at least one trench can penetrate through at least one or else all of the active zones.

In accordance with at least one embodiment, the at least one trench surrounds the first region in a lateral direction. “Lateral” denotes the directions parallel to the epitaxially grown semiconductor layer sequence of the semiconductor body. By way of example, the trench completely encloses the first region and encloses, in a plan view, a circular, rectangular or differently formed zone. First and second regions are then separated by the at least one trench, such that the semiconductor body is subdivided into the first and second regions by the trench.

In accordance with at least one embodiment, the second region completely surrounds the at least one trench and the first region in a lateral direction. The second region then forms a marginal three-dimensional partial structure of the semiconductor body which completely encloses both the at least one trench and the first region for example in a circular fashion, in a rectangular fashion or in a different fashion.

In accordance with at least one embodiment, the light-emitting diode chip comprises a semiconductor body having a first and a second region. Furthermore, the semiconductor body comprises an active zone within the semiconductor body, which active zone, during the operation of the light-emitting diode chip, emits electromagnetic radiation through a radiation coupling-out area formed at least in places by a first main area of the semiconductor body. Furthermore, the light-emitting diode chip comprises at least one trench in the semiconductor body, wherein parts of the semiconductor body are removed in the region of the trench. The at least one trench extends at least as far as the active zone, wherein the at least one trench completely surrounds the first region in a lateral direction. Furthermore, the second region completely surrounds the at least one trench and the first region in a lateral direction.

In this case the light-emitting diode chip described here is based on the insight inter alia, that damage to light-emitting diode chips particularly in the marginal region thereof leads to considerable quality problems that are difficult to monitor. By way of example, said damage occurs during further processing of the light-emitting diode chips or during a process of singulation into individual light-emitting diode chips.

In order, then, to provide a light-emitting diode chip which has no mechanical damage in a radiation-emitting region, the light-emitting diode chip described here makes use of the concept, inter alia, of introducing at least one trench into a semiconductor body of the light-emitting diode chip, wherein the at least one trench completely surrounds a first region in a lateral direction. By way of example, the first region is then the primarily radiation-emitting region of the semiconductor body and thus also of the light-emitting diode chip. Furthermore, a second region surrounds the at least one trench and the first region in a lateral direction. Both the second region and the trench can then form a marginal “protective region” which protects the first region against mechanical damage during a singulation process, for example. For this purpose, singulation is effected outside the first region and the at least one trench. Furthermore, the at least one trench introduced into the semiconductor body affords the possibility of monitoring the outer area of the semiconductor body in the region of the active zone visually for damage.

In accordance with at least one embodiment, an area of the semiconductor body which lies opposite the first main area of the light-emitting diode chip is provided with a reflector layer. The electromagnetic radiation emitted by the active zone within the semiconductor body is reflected back from the reflector layer in the direction of the radiation coupling-out area and is coupled out from the light-emitting diode chip through the radiation coupling-out area. By way of example, the area of the semiconductor body which lies opposite the first main area of the light-emitting diode chip is provided with the reflector layer in the first region, such that the radiation generated by the active zone in the first region of the semiconductor body is reflected by the reflector layer. It is likewise conceivable for the area to be provided with the reflector layer both in the first region and in the second region of the semiconductor body. Advantageously, as a result of this, the electromagnetic radiation generated by the active zone both in the first region and in the second region is reflected by the reflector layer in the direction of the radiation coupling-out area and then coupled out from the light-emitting diode chip. Such a reflector layer extending over the entire lateral extent of the first and of the second regions thus increases the coupling-out efficiency of the light-emitting diode chip.

“Coupling-out efficiency” is the ratio of luminous energy actually coupled out from the light-emitting diode chip to the luminous energy primarily generated within the light-emitting diode chip.

In accordance with at least one embodiment, the light-emitting diode chip comprises a carrier element and the reflector layer is arranged between the carrier element and the semiconductor body, wherein the semiconductor body is fixed to the carrier element by means of a connecting material. Preferably, the connecting material then mechanically connects the semiconductor body and the carrier element to one another. The connecting material can be a solder, for example. By way of example, the solder is then formed with a lead-free or lead-containing soldering tin. It is likewise possible for the connecting material to be formed with an adhesive. By way of example, the adhesive is a silver conductive adhesive. The carrier element is therefore not a growth substrate of the semiconductor body, rather a growth substrate can be removed from the semiconductor body.

In accordance with at least one embodiment the connecting material, at its side remote from the carrier element is covered completely by the semiconductor body and/or a passivation layer. The passivation layer is a boundary layer applied directly to the first main area of the semiconductor body, for example. The passivation layer advantageously prevents oxidation of the semiconductor material at the locations on which it is applied. In this context, it is conceivable for the side areas of the at least one trench actually to be formed by the semiconductor body, but for the base area of the trench to be formed by the connecting material. At the uncovered locations, the passivation layer can then be applied directly to the connecting material.

In accordance with at least one embodiment, the first region of the semiconductor body tapers in a direction proceeding from the carrier element towards the first main area of the semiconductor body. That is to say that the first region of the semiconductor body is bounded laterally in each case by at least one side area of the at least one trench and as a result the first region is reduced in terms of its lateral extent in a direction proceeding from the carrier element towards the first main area of the semiconductor body and is formed for example in a “funnel-shaped” fashion or in the manner of a truncated cone or truncated pyramid.

In accordance with at least one embodiment, the thicknesses of the first region and of the second region in a direction perpendicular to the first main area are substantially identical in magnitude. “Substantially” means that the two thicknesses of the first and of the second regions in the direction perpendicular to the first main area differ by less than 10%, particularly preferably by less than 5%.

In accordance with at least one embodiment, all side areas and a base area of the at least one trench are covered completely by the passivation layer. The base area is the area of the at least one trench which lies opposite the opening of the trench, wherein the base area connects at least two of the side areas to one another. By way of example, the at least one trench is formed in “U-” or “V”-shaped fashion in cross section.

In accordance with at least one embodiment, the radiation coupling-out area, in the region of the at least one trench and/or the second region of the semiconductor body, is provided with a metallization applied to the passivation layer. Preferably, the metallization and the passivation layer are in direct contact with one another.

In accordance with at least one embodiment, the at least one trench extends through the reflector layer.

In accordance with at least one embodiment the connecting material is in direct contact with the passivation layer in the regions of the light-emitting diode chip which have been removed from the reflector layer. In this context, it is conceivable for the passivation layer to be applied to the locations uncovered by the reflector layer being removed, for example of the base area of the at least one trench which is formed by the connecting material.

A method for producing a light-emitting diode chip is furthermore specified. By way of example, the method can be used to produce a light-emitting diode chip such as has been described in conjunction with one or more of the embodiments mentioned above. In other words, the features presented for the light-emitting diode chips described here are also disclosed for the method described here, and vice versa.

In a first step, a carrier assemblage of carrier elements is provided. The carrier assemblage can be formed for example in the manner of a wafer or a plate. By way of example, the carrier assemblage is formed with germanium or some other electrically conductive semiconductor material. Furthermore, it is conceivable for the material of the carrier assemblage to be doped.

In a further step, a semiconductor assemblage of semiconductor bodies is provided.

In a further step, the carrier assemblage and the semiconductor assemblage are connected by means of a connecting material to form an assemblage. By way of example, the connecting material is an electrically conductive solder.

In a further step, at least one trench is introduced into each semiconductor body, wherein parts of the semiconductor body are removed in the region of the trench. The at least one trench subdivides each semiconductor body into a first and a second region.

By way of example, the at least one trench is introduced into the semiconductor assemblage by means of at least one dry- and/or wet-chemical etching process or some other form of material removal.

In a further step, the assemblage is singulated outside the first region and the trench through the assemblage into at least one light-emitting diode chip along a separating line. By way of example, the assemblage is singulated by means of high-energy laser light. It is likewise possible for the assemblage to be singulated by means of scribing and subsequent breaking or cutting. During the singulation, the at least one trench advantageously acts as protection against mechanical damage to the first region in each semiconductor body. In this way, material residues produced by the singulation, for example, advantageously do not impair the semiconductor body in the first region since the trench defines a “separating region” in each light-emitting diode chip, which is in each case arranged between the singulation regions of the assemblage and the first regions of the semiconductor bodies.

In accordance with at least one embodiment, a light-emitting diode chip described here is produced by means of the method.

The light-emitting diode chip described here and also the method described here will be explained in greater detail below on the basis of exemplary embodiments and with reference to the associated figures.

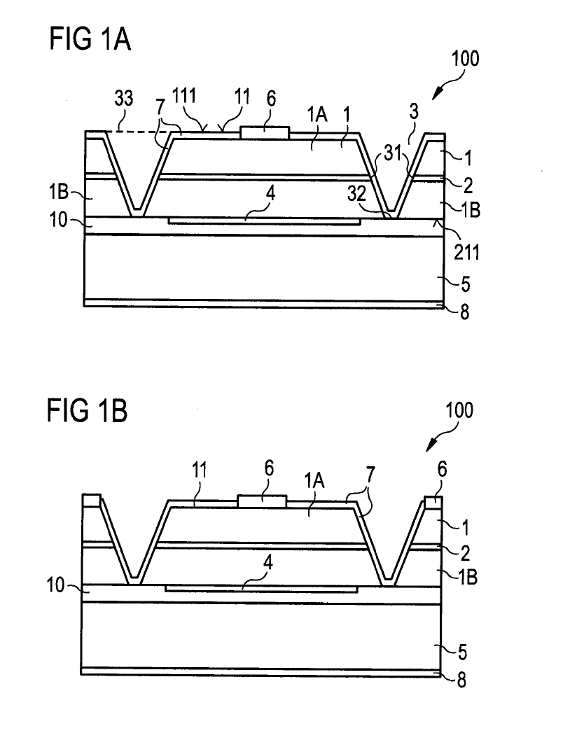

FIGS. 1A, 1B, 2A, 2B, 3, 4 and 5 show, in schematic sectional illustrations exemplary embodiments of a light-emitting diode chip described here.

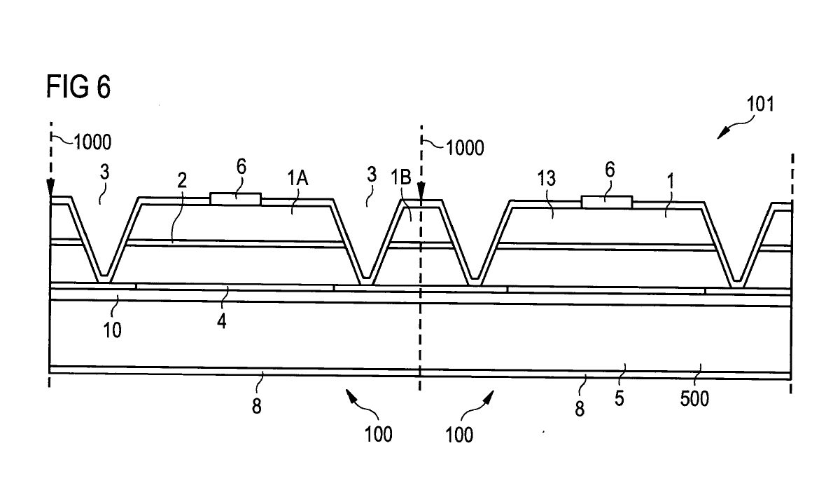

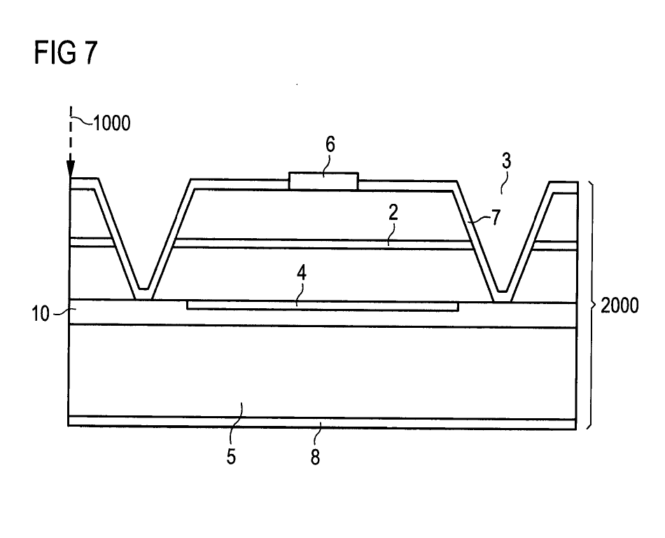

FIGS. 6 and 7 show, in schematic sectional illustrations, individual fabrication steps for producing an exemplary embodiment of a light-emitting diode chip described here.

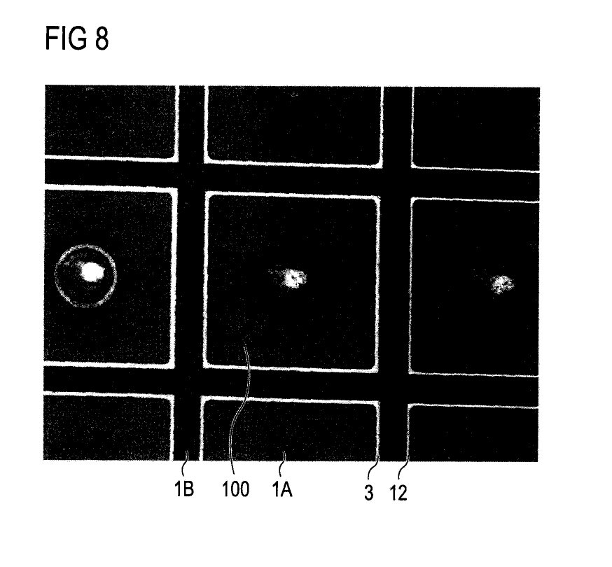

FIG. 8 shows, in a plan view, an assemblage of light-emitting diode chips.

In the exemplary embodiments and the figures, identical or identically acting constituent parts are in each case provided with the same reference symbols. The elements illustrated should not be regarded as true to scale; rather, individual elements may be illustrated with an exaggerated size in order to afford a better understanding.

FIG. 1 shows, on the basis of a schematic sectional illustration, a light-emitting diode chip 100 described here, comprising a semiconductor body 1. The semiconductor body 1 has an active zone 2 which, during the operation of the light-emitting diode chip 100 emits electromagnetic radiation through a radiation coupling-out area 11. In the present exemplary embodiment, the radiation coupling-out area 11 is partly formed by a first main area 111 of the semiconductor body 1. The semiconductor body 1 is preferably formed with a nitride-based compound semiconductor material such as gallium nitride. A trench 3 is introduced into the semiconductor body 1, wherein parts of the semiconductor body are removed in the region of the trench 3. The trench 3 is “U”-shaped in cross section and formed by two side areas 31 and also a base area 32 lying opposite an opening 33 of the trench 3. The base area 32 connects the side areas 31 to one another. The trench 3 penetrates through the active zone 2 completely, such that the trench 3 subdivides the active zone 2 in a lateral direction, that is to say for example parallel to the epitaxially grown semiconductor layer sequence of the semiconductor body 1.

The trench 3 completely surrounds a first region 1A of the semiconductor body 1, wherein a second region 1B of the semiconductor body 1 likewise completely encloses the one trench 3 and the first region 1A in a lateral direction. By way of example, the trench encloses the first region in a rectangular fashion, in a circular fashion or in an oval fashion.

An area 211 of the semiconductor body 1 which lies opposite the first main area 111 of the light-emitting diode chip is provided with a reflector layer 4. In the present case, the area 211 is provided with the reflector layer 4 only in the first region 1A of the semiconductor body 1 and reflects the electromagnetic radiation generated by the active zone 2 within the first region 1A towards the radiation coupling-out area 11, such that the reflector layer 4 increases the coupling-out efficiency of the light-emitting diode chip 100.

Furthermore, the light-emitting diode chip 100 comprises a carrier element 5 and the reflector layer 4 is arranged between the carrier element 5 and the semiconductor body 1. The semiconductor body 1 is fixed to the carrier element 5 by means of a connecting material 10. The connecting material 10 can be a metallic solder, for example, which mechanically and electrically connects the semiconductor body 1 and the carrier element 5 to one another.

The light-emitting diode chip 100 is provided with an electrical contact 6 at the first region 1A of the semiconductor body 1. Furthermore, a further electrical contact-connection 8 is applied to an area of the carrier element 5 which is remote from the semiconductor body 1.

All side areas 31, a base area 32 of the trench 3 and also all uncovered locations of the main area 111 are completely covered by a passivation layer 7. The passivation layer 7 prevents oxidation of the uncovered locations of the semiconductor body 1 and is applied directly to all the uncovered locations of the main area 111 of the semiconductor body 1. In this context, “applied directly” means that the passivation layer 7 is preferably in direct contact with the main area 111 and, therefore, neither a gap nor an interruption nor an interlayer is formed between the main area 111 and the passivation layer 7. By way of example, the passivation layer 7 is formed with one of the materials silicon dioxide, silicon nitride, titanium dioxide and/or silicon dioxide. By way of example, the passivation layer 7 is formed completely with one of the materials mentioned or is formed with layers composed of these materials. Furthermore, it is possible for different layers composed of the materials mentioned to be applied alternately to the main area 111 of the semiconductor body 1.

By virtue of the fact that the trench 3 extends completely through the semiconductor body 1 and the base area 32 of the trench 3 is therefore formed by the connecting material 10, the connecting material 10, at its side remote from the carrier element 5, is covered completely by the semiconductor body 1 and the passivation layer 7. In other words, the connecting material 10 is not covered by the semiconductor body 1 only in the region of the base area 32 of the trench 3.

By virtue of the “U”-shaped embodiment of the trench 3, the first region 1A tapers in a direction proceeding from the carrier element 5 towards the first main area 111 of the semiconductor body 1. The first region 1A of the semiconductor body 1 is therefore bounded laterally by the side areas 31 and the radiation coupling-out area 11. Furthermore, the second region 1B also has a part of the active zone 2, but is not electrically contact-connected there and is thus radiation-inactive.

In contrast to the exemplary embodiment in accordance with FIG. 1A, the exemplary embodiment in FIG. 1B shows that the main area 111 of the semiconductor body 1 is provided with the electrical contact 6 additionally in the second region 1B of the semiconductor body 1, but is not electrically contact-connected externally in this region and therefore serves as a passivation layer for the semiconductor body 1 at these locations, for example.

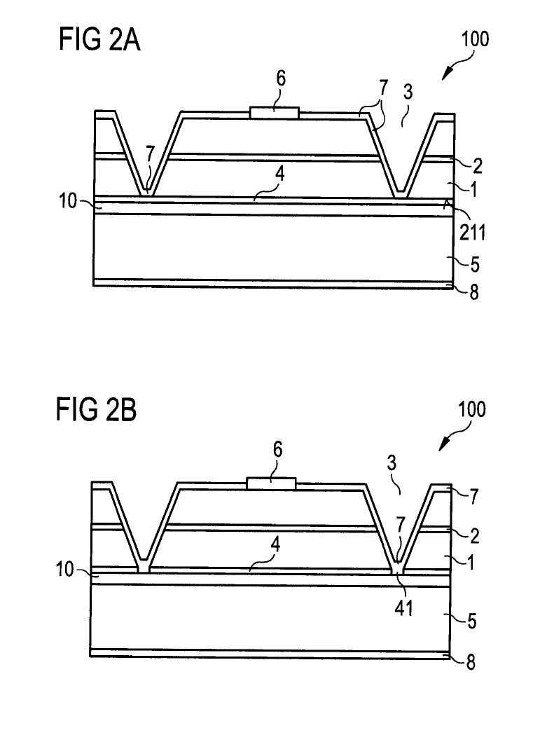

FIG. 2A shows that the reflector layer 4 can extend over the entire lateral extent of the light-emitting diode chip 100. That is to say that the area 211 is provided with the reflector layer 4 both in the first region 1A and in the second region 1B of the semiconductor body 1. The larger lateral extent of the reflector layer 4 advantageously enables an increased coupling-out efficiency of the light-emitting diode chip 100 in comparison with the exemplary embodiments mentioned above.

In the case of the exemplary embodiment in accordance with FIG. 2B, the connecting material 10 is in direct contact with the passivation layer 7 in the regions 41 of the light-emitting diode chip 100 which have been removed from the reflector layer 4. That is to say that the reflector layer 4 is removed in the regions 41 and the passivation layer 7 is deposited in the regions 41. The passivation layer 7 preferably fills regions 41 in a form-fitting fashion. Here “in a form-fitting fashion” means that the passivation layer is in direct contact with the surrounding material within the region 41 and, by way of example, no air inclusion is formed in the region 41. This advantageously prevents, for example, ions of the reflector layer 4 from being detached from the reflector layer 4 in the region 41 or the reflector layer 4 from being oxidized in the region 41.

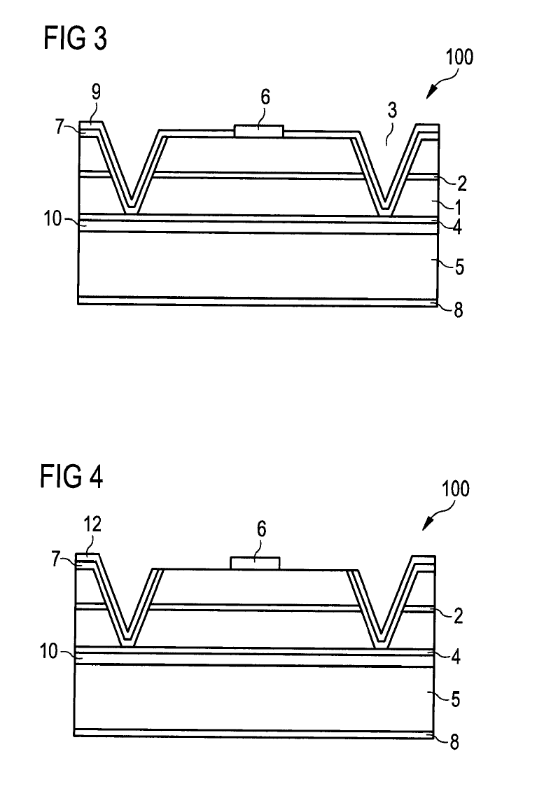

In contrast to the exemplary embodiment in FIG. 2A, FIG. 3 shows that the passivation layer 7 only covers the side areas 31, the base area 32 of the trench 3 and the main area 111 in the second region 1B of the semiconductor body 1. Furthermore, a further passivation layer 9 is applied to all locations of the first main area 111 which are not covered by the electrical contact-connection 6. By way of example, the further passivation layer 9 is formed with silicon dioxide.

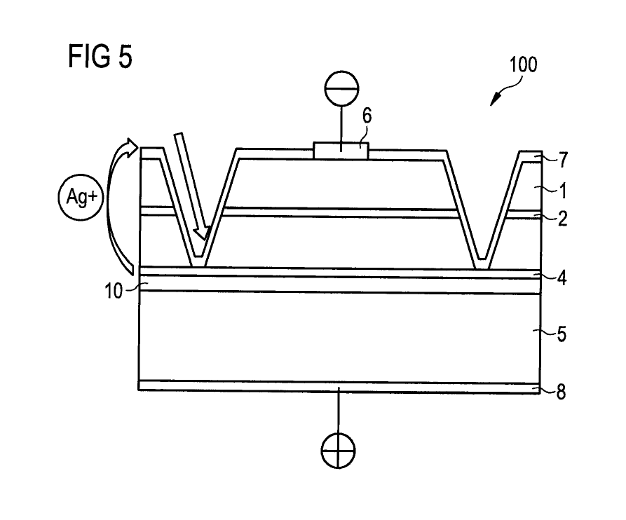

FIG. 4 shows, in a departure from the light-emitting diode chip 100 in FIG. 3, that, instead of the further passivation layer 9, a metallization 12 is applied to the passivation layer 7. The first main area 111 is therefore provided with the metallization 12 in the region of the trench 3 and the second region 1B of the semiconductor body 1, said metallization being applied to the passivation layer 7. By way of example, the radiation coupling-out area 11 is then free of any layer in the first region 1A. Advantageously, during singulation into individual light-emitting diode chips 100, for example by means of high-energy laser light, the electromagnetic radiation is absorbed by the metallization 12 as a result of which the separating operation is initiated from the metallization 12. The metallization 12 reduces for example “flakes” of the semiconductor material in the second region 1B of the semiconductor body 1.

FIG. 5 shows the light-emitting diode chip 100 from FIG. 2A, in which the electrical contact 6 forms the n-side contact and the further electrical contact-connection 8 forms the p-side contact of the light-emitting diode chip 100. If the light-emitting diode chip 100 is surrounded by a regime having high humidity, then it is possible for silver ions of the reflector layer 4 to be detached by the moisture and to migrate along outer areas of the light-emitting diode chip 100 in the direction of the electrical contact 6 (also called ion migration). The trench 3 advantageously prevents a short circuit between the electrical contact 6 and the silver ions since the silver ions, within the trench 3, would have to fight against the electric field situated in the trench 3. The electric field in the trench 3 therefore forms a potential barrier for the positively charged silver ions. A short circuit between the silver ions and the electrical contact 6 is thus prevented, which has the consequence of considerably increasing not only the lifetime of the light-emitting diode chip, but likewise the reliability thereof during operation, for example.

A method described here for producing a light-emitting diode chip 100 in accordance with at least one embodiment will be explained in greater detail in conjunction with FIGS. 6 and 7, on the basis of a schematic sectional illustration.

FIG. 6 shows a carrier assemblage 500 of carrier elements 5. The carrier assemblage 500 can be formed with a semiconductor material, such as germanium for example. By way of example, the carrier assemblage 500 is present in the form of wafers or plates.

In a next step, a semiconductor assemblage 13 of semiconductor bodies 1 is provided. The semiconductor assemblage 13 can be formed with an epitaxially grown semiconductor layer sequence, comprising an active zone 2 for the emission of electromagnetic radiation. The semiconductor assemblage 13 is preferably formed with a nitride-based compound material, for example gallium nitride.

In a next step, the carrier assemblage 500 and the semiconductor assemblage 13 are connected by means of a connecting material 10. By way of example, the connecting material 10 is applied to an outer area of the carrier assemblage 500 for this purpose. A connecting material 10 can be an electrically conductive solder. The carrier assemblage 500 and the semiconductor assemblage 13 then together form an assemblage 101.

In a further step, a trench 3 is introduced into each semiconductor body 1, wherein parts of the semiconductor body are removed in the region of the trench 3 and the trench 3 subdivides the semiconductor body 1 into a first region 1A and a second region 1B. By way of example, the trench 3 is introduced into each semiconductor body 1 by means of at least one dry- and/or wet-chemical etching process.

Each semiconductor body 1 is provided with an electrical contact 6 in the first region 1A, wherein, at the same time, all locations not covered by the electrical contact 6 on that area of the semiconductor assemblage 13 which is remote from the carrier assemblage 500 are provided with a passivation layer 7. Furthermore, an area of the carrier assemblage 500 which lies opposite the semiconductor assemblage 13 is provided with an electrical contact-connection 8.

It is likewise possible for a reflector layer 4 to be applied before the application of the semiconductor assemblage 13 to the connecting material 10 at locations of the subsequent regions 1A of each semiconductor body 1. The reflector layer 4 can be formed for example with a metallic material, in particular a silver. Furthermore, it is conceivable for the reflector layer 4 to be applied as a continuous layer over the entire lateral extent of the carrier assemblage 500.

In a next step, the assemblage 101 is singulated outside the first region 1A and the trench 3 through the assemblage 101 into a multiplicity of light-emitting diode chips 100 along a separating line 1000. The singulation can be effected by means of high-energy laser light, for example. It is likewise possible for the singulation to be effected by means of scribing and subsequent breaking or cutting.

As a result of the use of gallium nitride as semiconductor material for the semiconductor assemblage 13, a good separating quality through the semiconductor material arises particularly in the case of singulation by means of high-energy laser light. That is to say that the material removal produced by the laser light is as small as possible.

Furthermore, the trench 3 serves as protection against mechanical damage that can occur during separation or during further processing of the individual light-emitting diode chips 100. Furthermore, as a result of the protection function of the trench 3 during singulation, the passivation layer 7 is not damaged in the region 1A.

Likewise, flakes of the passivation layer 7 that are produced during singulation outside the trench 3 and the first region 1A are avoided by means of the trench 3, as a result of which the passivation layer 7 remains undamaged in the region 1A.

FIG. 7 shows such a singulated light-emitting diode chip 100 produced by means of singulation of the assemblage 101 outside the trench 3 and the first region 1A. The light-emitting diode chip 100 exhibits singulation traces merely in the region 2000, said singulation traces being restricted exclusively to the second region 1B of the semiconductor body 1, as a result of which the region 1A of the semiconductor body 1 has no damage whatsoever as a result of the singulation.

FIG. 8 shows such an assemblage 101 in a plan view. Both the first regions 1A and the second regions 1B of each light-emitting diode chip 100 can be discerned. The first region 1A is in each case completely enclosed by the trench 3 in a rectangular fashion, wherein the trench 3 is simultaneously provided with the metallization 12.

The invention described here is not restricted by the description on the basis of the exemplary embodiments. Rather, the invention encompasses any novel feature and also any combination of features, which in particular includes any combination of features in the patent claims. This holds true even if this feature or this combination itself is not explicitly specified in the patent claims or the exemplary embodiments.

1. A light-emitting diode chip, comprising:
a semiconductor body having a first and a second region;
an active zone within the semiconductor body, which active zone, during the operation of the light-emitting diode chip, emits electromagnetic radiation through a radiation coupling-out area formed at least in places by a first main area of the semiconductor body;
at least one trench in the semiconductor body wherein parts of the semiconductor body are removed in the region of the trench,
wherein the at least one trench extends at least as far as the active zone,
wherein the at least one trench completely surrounds the first region in a lateral direction, and
wherein the second region completely surrounds the at least one trench and the first region in a lateral direction.

2. The light-emitting diode chip according to claim 1, wherein an area of the semiconductor body which lies opposite the first main area of the light-emitting diode chip is provided with a reflector layer.

3. The light-emitting diode chip according claim 1, wherein the light-emitting diode chip comprises a carrier element and the reflector layer is arranged between the carrier element and the semiconductor body, and wherein the semiconductor body is fixed to the carrier element by means of a connecting material.

4. The light-emitting diode chip according to claims claim 1, wherein the connecting material, at its side remote from the carrier element is covered completely by the semiconductor body and/or a passivation layer.

5. The light-emitting diode chip according to claim 4, wherein the connecting material is not covered by the semiconductor body only in the region of the at least one trench.

6. The light-emitting diode chip according to claim 1, wherein the first region of the semiconductor body tapers in a direction proceeding from the carrier element towards the first main area of the semiconductor body.

7. The light-emitting diode chip according to claim 1, wherein the thicknesses of the first region and of the second region in a direction perpendicular to the first main area are substantially identical in magnitude.

8. The light-emitting diode chip (100) according to claim 4, wherein all side areas and a base area of the at least one trench are covered completely by the passivation layer.

9. The light-emitting diode chip according to claim 8, wherein the radiation coupling-out area, in the region of the at least one trench and/or the second region of the semiconductor body, is provided with a metallization applied to the passivation layer.

10. The light-emitting diode chip according to claim 2, wherein the at least one trench extends through the reflector layer.

11. The light-emitting diode chip according to claim 4, wherein the connecting material is in direct contact with the passivation layer in the regions of the light-emitting diode chip which have been removed from the reflector layer.

12. A method for producing a light-emitting diode chip comprising the steps of:
providing a carrier assemblage of carrier elements;
providing a semiconductor assemblage of semiconductor bodies;
connecting the carrier assemblage (500) and the semiconductor assemblage (13) by means of a connecting material to form an assemblage;
introducing at least one trench into each semiconductor body, wherein parts of the semiconductor body are removed in the region of the trench and the trench subdivides the semiconductor body into a first and a second region; and
singulating the assemblage composed of carrier assemblage and semiconductor assemblage outside the first region and the trench through the assemblage into at least one light-emitting diode chip along a separating line.

13. The method according to the claim 12, wherein the light-emitting diode chip is produced, said light-emitting diode chip comprises:
a semiconductor body having a first and a second region;
an active zone within the semiconductor body, which active zone, during the operation of the light-emitting diode chip, emits electromagnetic radiation through a radiation coupling-out area formed at least in places by a first main area of the semiconductor body and
at least one trench in the semiconductor body wherein parts of the semiconductor body are removed in the region of the trench,
wherein the at least one trench extends at least as far as the active zone,
wherein the at least one trench completely surrounds the first region in a lateral direction,
wherein the second region completely surrounds the at least one trench and the first region in a lateral direction,
wherein an area of the semiconductor body which lies opposite the first main area of the light-emitting diode chip is provided with a reflector layer,
wherein the light-emitting diode chip comprises a carrier element and the reflector layer is arranged between the carrier element and the semiconductor body, wherein the semiconductor body is fixed to the carrier element by means of the connecting material,
wherein all side areas and a base area of the at least one trench are covered completely by a passivation layer,
wherein the at least one trench extends through the reflector layer, and
wherein the connecting material is in direct contact with the passivation layer in the regions of the light-emitting diode chip which have been removed from the reflector layer.

14. A light-emitting diode chip, comprising:
a semiconductor body having a first and a second region;
an active zone within the semiconductor body, which active zone, during the operation of the light-emitting diode chip, emits electromagnetic radiation through a radiation coupling-out area formed at least in places by a first main area of the semiconductor body; and
at least one trench in the semiconductor body, wherein parts of the semiconductor body are removed in the region of the trench,
wherein the at least one trench extends at least as far as the active zone,
wherein the at least one trench completely surrounds the first region in a lateral direction,
wherein the second region completely surrounds the at least one trench and the first region in a lateral direction,
wherein an area of the semiconductor body which lies opposite the first main area of the light-emitting diode chip is provided with a reflector layer,
wherein the light-emitting diode chip comprises a carrier element and the reflector layer is arranged between the carrier element and the semiconductor body, wherein the semiconductor body is fixed to the carrier element by means of a connecting material,
wherein all side areas and a base area of the at least one trench are covered completely by a passivation layer,
wherein the at least one trench extends through the reflector layer, and
wherein the connecting material is in direct contact with the passivation layer in the regions of the light-emitting diode chip which have been removed from the reflector layer.
